(19) United States
(12) Patent Application Publication
(10) Pub. No.: US 2021/0343847 A1
(43) Pub. Date: Nov. 4, 2021

(54) DIFFUSION AND/OR ENHANCEMENT LAYERS FOR ELECTRICAL CONTACT REGIONS

(71) Applicant: Cree, Inc., Durham, NC (US)

(72) Inventors: Daniel Jenner Lichtenwalner, Raleigh, NC (US); Edward Robert Van Brunt, Raleigh, NC (US)

(21) Appl. No.: 16/863,642

(22) Filed: Apr. 30, 2020

(51) Int. Cl. H01L 29/423; H01L 29/16; H01L 29/06; H01L 29/78

(52) U.S. Cl. CPC H01L 29/4238; H01L 29/1608; H01L 29/7802; H01L 29/0638; H01L 29/0649

(57) ABSTRACT

Power switching devices include a semiconductor layer structure comprising an active region and an inactive region, the active region comprising a plurality of unit cells and the inactive region comprising a gate pad on the semiconductor layer structure and a gate bond pad on and electrically connected to the gate pad, an isolation layer between the gate pad and the gate bond pad, and a barrier layer between the gate pad and the isolation layer.

### FIELD

The present invention relates to semiconductor devices and, more particularly, to power semiconductor switching devices.

### BACKGROUND

The Metal Oxide Semiconductor Field Effect Transistor (“MOSFET”) is a well known type of semiconductor transistor that may be used as a switching device. A MOSFET is a three terminal device that includes a source region and a drain region that are separated by a channel region, and a gate electrode that is disposed adjacent the channel region. A MOSFET may be turned on or off by applying a gate bias voltage to the gate electrode. When a MOSFET is turned on (i.e., it is in its “on-state”), current is conducted through the channel region of the MOSFET between the source region and the drain region. When the bias voltage is removed from the gate electrode (or reduced below a threshold level), the current ceases to conduct through the channel region. By way of example, an n-type MOSFET has n-type source and drain regions and a p-type channel. An n-type MOSFET thus has an “n-p-n” design. An n-type MOSFET turns on when a gate bias voltage is applied to the gate electrode that is sufficient to create a conductive n-type inversion layer in the p-type channel region that electrically connects the n-type source and drain regions, thereby allowing for majority carrier conduction therebetween.

The gate electrode of a power MOSFET is typically separated from the channel region by a thin gate insulating pattern, such as a silicon oxide pattern. Because the gate electrode of the MOSFET is insulated from the channel region by the gate insulating pattern, minimal gate current is required to maintain the MOSFET in its on-state or to switch the MOSFET between its on-state and its off-state. The gate current is kept small during switching because the gate forms a capacitor with the channel region. Thus, only minimal charging and discharging current is required during switching, allowing for less complex gate drive circuitry.

The bipolar junction transistor (“BJT”) is another well known type of semiconductor transistor that is also routinely used as a switching device. A BJT includes two p-n junctions that are formed in close proximity to each other in the semiconductor material. In operation, charge carriers enter a first region of the semiconductor material (the emitter) that is adjacent one of the p-n junctions. Most of the charge carriers exit the device from a second region of the semiconductor material (the collector) that is adjacent the other p-n junction. The collector and emitter are formed in regions of the semiconductor material that have the same conductivity type. A third, relatively thin region of the semiconductor material, known as the base, is positioned between the collector and the emitter and has a conductivity type that is opposite the conductivity type of the collector and the emitter. Thus, the two p-n junctions of the BJT are formed where the collector meets the base and where the base meets the emitter. By flowing a small current through the base of a BJT, a proportionally larger current passes from the emitter to the collector.

BJTs are current controlled devices in that a BJT is turned “on” (i.e., it is biased so that current flows between the emitter and the collector) by flowing a current through the base of the transistor. For example, in an n-p-n BJT (i.e., a BJT that has n-type collector and emitter regions and a p-type base region), the transistor is typically turned on by applying a positive voltage to the base to forward bias the base-emitter p-n junction. When the device is biased in this manner, the hole current that flows into the base of the transistor is injected into the emitter. The holes are referred to as “majority carriers” because the base is a p-type region, and holes are the “normal” charge carriers in such a region. In response to the hole current into the emitter, electrons are injected from the emitter into the base, where they diffuse toward the collector. These electrons are referred to as “minority carriers” because electrons are not the normal charge carrier in the p-type base region. The device is referred to as a “bipolar” device because the emitter-collector current includes both electron and hole current.

A BJT may require a relatively large base current to maintain the device in its on-state. As such, relatively complex external drive circuits may be required to supply the relatively large base currents that can be required by high power BJTs. Moreover, the switching speeds of BJTs may be significantly slower than the switching speeds of power MOSFETs due to the bipolar nature of the current conduction.

A third well known type semiconductor switching device is the Insulated Gate Bipolar Transistor (“IGBT”), which is a device that combines the high impedance gate of the power MOSFET with the small on-state conduction losses of the power BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit.

There is an increasing demand for high power semiconductor switching devices that can pass large currents in their “on” state and block large voltages (e.g., hundreds or even thousands of volts) in their reverse blocking state. In order to support high current densities and block such high voltages, power MOSFETs and IGBTs typically have a vertical structure with the source and drain on opposite sides of a thick semiconductor layer structure in order to block higher voltage levels. In very high power applications, the semiconductor switching devices are typically formed using wide band-gap semiconductor material systems (herein, the term “wide band-gap semiconductor” encompasses any semiconductor having a band-gap of at least 1.4 eV) such as, for example, silicon carbide (“SiC”), which has a number of advantageous characteristics including, for example, a high electric field breakdown strength, high thermal conductivity, high electron mobility, high melting point and high-saturated electron drift velocity. Relative to devices formed using other semiconductor materials such as, for example, silicon, electronic devices formed using silicon carbide may have the capability of operating at higher temperatures, at high power densities, at higher speeds, at higher power levels and/or under high radiation densities.

### SUMMARY

Pursuant to some embodiments of the present invention, a semiconductor device includes a semiconductor layer structure comprising an active region and an inactive region, the active region comprising a plurality of unit cells and the inactive region comprising a gate pad on the semiconductor layer structure and a gate bond pad on and electrically connected to the gate pad, an isolation layer between the gate pad and the gate bond pad, and a barrier layer between the gate pad and the isolation layer.

In some embodiments, wherein the barrier layer is a first barrier layer, and the semiconductor device further includes a second barrier layer on the gate pad and on the first barrier layer.

In some embodiments, at least a portion of the isolation layer is between the first barrier layer and the second barrier layer.

In some embodiments, the barrier layer comprises multiple layers.

In some embodiments, the barrier layer comprises titanium (Ti) and/or tantalum (Ta).

In some embodiments, the barrier layer is a first barrier layer, and the semiconductor device further includes a gate finger on the active region and electrically connected to the gate bond pad, and a second barrier layer on the gate finger.

In some embodiments, the second barrier layer is on a top surface and a sidewall of the gate finger.

In some embodiments, the barrier layer is a first barrier layer, and the semiconductor device further includes a source contact on the semiconductor layer structure, a second barrier layer on sidewalls and a bottom surface of the source contact, and a third barrier layer between the semiconductor layer structure and the second barrier layer.

Pursuant to some embodiments of the present invention, a semiconductor device includes a semiconductor substrate, a gate pad on the semiconductor substrate, a gate bond pad on and electrically connected to the gate pad, a first barrier layer between a bottom portion of gate bond pad and the gate pad in a first direction perpendicular to a top surface of the semiconductor substrate, and a second barrier layer between the gate pad and the first barrier layer in the first direction.

In some embodiments, the second barrier layer has a width in a second direction that is parallel to a top surface of the semiconductor substrate that exceeds that of a portion of the first barrier layer that is between the second barrier layer and a bottom portion of the gate bond pad.

In some embodiments, a thickness of the second barrier layer is substantially uniform along the width of the second barrier layer in the second direction.

In some embodiments, the gate bond pad is coupled to the gate pad via a contact hole having opposing sidewalls, a portion of the first barrier layer is on the opposing sidewalls of the contact hole, and a width of the second barrier layer in a second direction that is parallel to a top surface of the semiconductor substrate is greater than a width of the contact hole in the second direction.

In some embodiments, the semiconductor device further includes an isolation layer, wherein a portion of the isolation layer is between the second barrier layer and the gate bond pad.

In some embodiments, the second barrier layer comprises multiple layers.

In some embodiments, the second barrier layer comprises titanium (Ti) and/or tantalum (Ta).

In some embodiments, the second barrier layer is on a top surface and a sidewall of the gate pad.

In some embodiments, a material of the second barrier layer is different from a material of the first barrier layer.

In some embodiments, the semiconductor device further includes a semiconductor layer structure comprising an active region and an inactive region, wherein the gate pad is on the inactive region, a gate finger on the active region and electrically connected to the gate pad, and a third barrier layer on the gate finger.

In some embodiments, the third barrier layer is on a top surface and a sidewall of the gate finger.

Pursuant to some embodiments of the present invention, a semiconductor device includes a semiconductor substrate, a gate pad on the semiconductor substrate, an isolation layer on the gate pad, a first barrier layer on the isolation layer and the gate pad, and a second barrier layer between the gate pad and the first barrier layer in a first direction, the second barrier layer having a width in a second direction that exceeds a width of the first barrier layer in the second direction.

In some embodiments, the semiconductor device further includes a gate bond pad on and electrically connected to the gate pad via a contact hole in the isolation layer having opposing sidewalls, the first barrier layer comprises a first portion that extends in the second direction between the opposing sidewalls of the contact hole, and the width of the second barrier layer in the second direction exceeds a width of the first portion of the first barrier layer in the second direction.

In some embodiments, a portion of the isolation layer is between the second barrier layer and the gate bond pad.

In some embodiments, the isolation layer is on a top surface of the second barrier layer and on a sidewall of the first barrier layer.

Pursuant to some embodiments of the present invention, a semiconductor device includes a semiconductor layer structure, a plurality of unit cell transistors that are electrically connected in parallel, each unit cell transistor including a gate finger that extends in a first direction on a top surface of the semiconductor layer structure, the gate fingers spaced apart from each other along a second direction, and an auxiliary gate electrode barrier layer on an upper surface of each of the gate fingers.

In some embodiments, the gate finger comprises polysilicon.

In some embodiments, the auxiliary gate electrode barrier layer comprises titanium (Ti) and/or tantalum (Ta).

In some embodiments, the auxiliary gate electrode barrier layer is also on opposing sidewalls of each of the gate fingers.

In some embodiments, the semiconductor layer structure comprises an inactive region and an active region, and the active region comprises the plurality of unit cell transistors. The inactive region includes: a gate pad on the semiconductor layer structure; a gate bond pad on and electrically connected to the gate pad; an isolation layer between the gate pad and the gate bond pad; and an auxiliary gate pad barrier layer between the gate pad and the isolation layer.

In some embodiments, the auxiliary gate pad barrier layer is on a top surface and a sidewall of the gate pad.

In some embodiments, the semiconductor device further includes a gate pad barrier layer between the auxiliary gate pad barrier layer and the gate bond pad.

In some embodiments, the auxiliary gate electrode barrier layer comprises multiple layers.

In some embodiments, the semiconductor device further includes a source contact on the semiconductor layer structure, a source barrier layer on sidewalls and a bottom surface of the source contact, and an auxiliary source barrier layer between the semiconductor layer structure and the source barrier layer.

In some embodiments, the semiconductor device further includes an isolation layer on the gate finger, and the auxiliary gate electrode barrier layer is between the isolation layer and the gate finger.

### BRIEF DESCRIPTION OF DRAWINGS

FIG. 1 is a schematic plan view of a semiconductor wafer that includes a plurality of power switching devices according to embodiments of the present invention.

FIG. 2A is a schematic plan view of one of the power switching devices included on the semiconductor wafer of FIG. 1.

FIG. 2B is a schematic plan view of the power switching device of FIG. 2A with the source and gate metallization removed.

FIG. 3A is a schematic cross-sectional diagram taken along the line A-A′ of FIG. 2B that illustrates the unit cell structure in an active region, and the gate pad in an inactive region, of a conventional device. FIG. 3B is a schematic cross-sectional diagram of portion A of FIG. 3A. FIG. 3C is a schematic cross-sectional diagram of portion B of FIG. 3A.

FIG. 4A illustrates a semiconductor device according to some embodiments described herein. FIG. 4B is a schematic cross-sectional diagram of portion A of FIG. 4A. FIG. 4C illustrates an additional semiconductor device according to some embodiments described herein.

FIGS. 5A and 5B illustrate additional semiconductor devices according to some embodiments described herein.

FIG. 6A illustrates an additional semiconductor device according to some embodiments described herein. FIG. 6B is a schematic cross-sectional diagram of portion B of FIG. 6A. FIGS. 6C to 6E illustrate additional semiconductor devices according to some embodiments described herein.

FIGS. 7-12 illustrate methods of manufacturing semiconductor devices according to embodiments described herein.

### DETAILED DESCRIPTION

Power silicon carbide MOSFETs are in use today for applications requiring high voltage blocking such as voltage blocking of 5,000 volts or more. By way of example, silicon carbide MOSFETs are commercially available that are rated for current densities of 10 A/cm² or more that will block voltages of at least 10 kV. To form such devices, a plurality of “unit cells” are typically formed, where each unit cell includes a MOSFET transistor. In high power applications, a large number of these unit cells (e.g., hundreds or thousands) are typically provided on a single semiconductor substrate, and a gate electrode pattern is formed on a top side of the semiconductor substrate that acts as the gate electrode for all of the unit cells. The opposite (bottom) side of the semiconductor substrate acts as a common drain for all of the units cells of the device. A plurality of source contacts are formed on source regions in the semiconductor layer structure that are exposed within openings in the gate electrode pattern. These source contacts are also electrically connected to each other to serve as a common source. The resulting device has three terminals, namely a common source terminal, a common drain terminal and a common gate electrode that act as the terminals for the hundreds or thousands of individual unit cell transistors. It will be appreciated that the above description is of an n-type MOSFET; the locations of the drain and source would be reversed for a p-type MOSFET.

The gate electrode pattern of a power MOSFET may be implemented by forming a patterned conductive layer that includes a plurality of elongated gate fingers that extend through an active region of the device. The patterned conductive layer may comprise a semiconductor layer such as, for example, a polysilicon layer and/or doped silicon (Si). The patterned conductive layer may also include a gate pad in an inactive region of the device, and each gate finger may connect to the gate pad, either directly or by one or more gate buses and/or conductive vias.

The present disclosure describes an approach to improve diffusion barrier protection between a device layer and a metallization layer, while simultaneously modifying the conductivity and adhesion between the layers. This may be particularly useful for improving the gate contact regions in a power transistor (e.g., a MOSFET or an IGBT).

Embodiments described herein may add a material layer (such as TiN, other metal nitrides, and/or intermetallics) to the top of a conducting layer such as the gate pad and/or gate electrode (typically doped Si or a silicide material), a source contact, and/or other layer needing an additional contact such as a current or temperature sensing device within a power device. The material layer may have the properties of a diffusion barrier, an enhanced conduction layer, and/or an adhesion layer to the contact regions above it (insulating and/or conducting layers).

Metals such as those used in metal layers typically have large amounts of impurities which can deleteriously affect semiconductors or metal-insulator-semiconductor interfaces; thus improved barrier performance may be useful for semiconductor devices.

Aspects of the present invention will now be discussed in greater detail with reference to the attached figures, in which example embodiments of the present invention are illustrated.

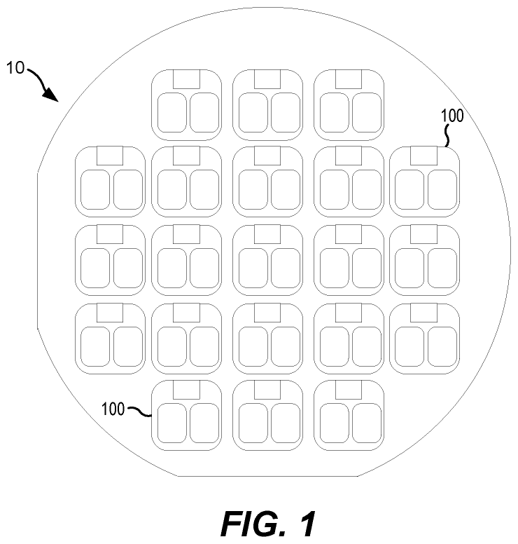

FIG. 1 is a schematic plan view of a wafer 10 that includes a plurality of power switching devices according to embodiments of the present invention. Referring to FIG. 1, the wafer 10 may be a thin planar structure that includes a semiconductor layer structure with other material layers such as insulating layers and/or metal layers formed thereon. The semiconductor layer structure may include a semiconductor substrate and/or a plurality of other semiconductor layers. A plurality of power switching devices 100 may be formed using the wafer 10. The switching devices 100 may be formed in rows and columns and may be spaced apart from each other so that the wafer 10 may later be singulated (e.g., diced) to separate the individual switching devices 100 for packaging and testing. The wafer 10 may comprise a silicon carbide substrate having one or more silicon carbide layers formed thereon (e.g., by epitaxial growth) in some embodiments. Other semiconductor layers (e.g., polysilicon layers), insulating layers, and/or metal layers may be formed on the silicon carbide semiconductor layer structure to form the power switching devices 100. The silicon carbide substrate and the silicon carbide layers formed thereon may be 4H silicon carbide in some embodiments.

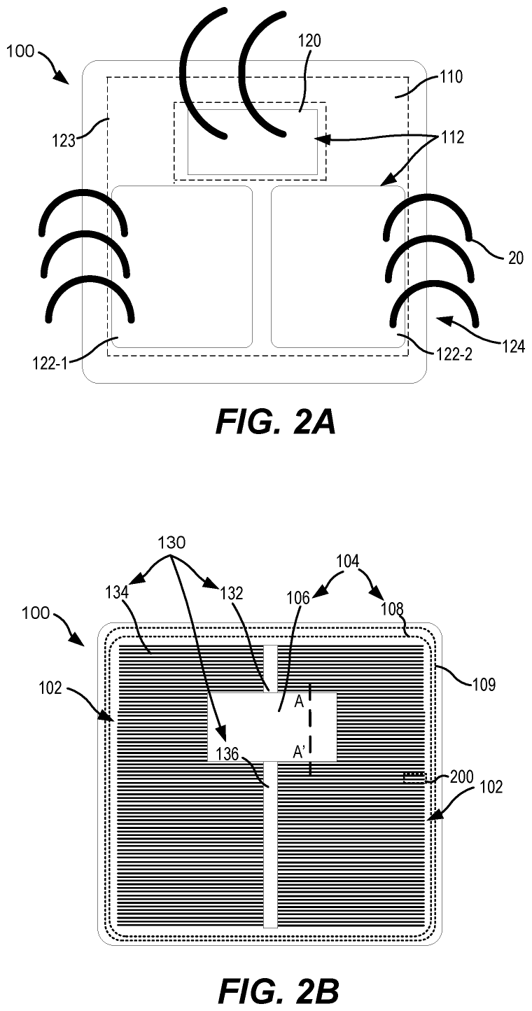

FIG. 2A is a schematic plan view of one of the power switching devices 100 included on the semiconductor wafer 10 of FIG. 1. FIG. 2B is a schematic plan view of the power switching device 100 of FIG. 2A with the source and gate metallization removed. In the description below it is assumed that the power switching device 100 is an n-type power MOSFET 100.

As shown in FIG. 2A, a protective layer 110 covers a substantial portion of the top surface of the power MOSFET 100. The protective layer 110 may be formed, for example, of polyamide. Various bond pads may be exposed through openings 112 in the protective layer 110. The bond pads may include a gate bond pad 120 and one or more source bond pads 122. The configuration, shape, and structure of the gate bond pad 120 and source bond pads 122 illustrated in FIG. 2A are merely examples, and the embodiments described herein are not limited thereto. Two source bond pads 122-1, 122-2 are illustrated in FIG. 2A. While not visible in FIG. 2A, a drain contact and/or bond pad 124 may be provided on the bottom side of the MOSFET 100. The bond pads 120, 122, 124 may be formed of a metal, such as aluminum, that bond wires can be readily attached to via conventional techniques such as thermo-compression or soldering. As will be discussed in more detail below, source contacts are provided that contact a semiconductor layer structure of the MOSFET 100. The source contacts may be lower portions of a source metal pattern 123 that extends across much of the upper surface of the MOSFET 100 (e.g., all but the portion of the upper surface of the MOSFET 100 occupied by the gate bond pad 120). The source bond pads 122-1, 122-2 may comprise portions of the source metal pattern 123 that are exposed by the openings 112 in the protective layer 110. Bond wires 20 are shown in FIG. 2A that may be used to connect the gate bond pad 120 and the source bond pads 122-1, 122-2 to external voltage sources (not shown) such as terminals of other circuit elements.

As is shown in FIG. 2B, the MOSFET 100 includes a semiconductor layer structure that includes an active region 102 and an inactive region 104. The active region 102 is an area of the device that includes operable transistors (e.g., the unit cell transistors discussed herein), while the inactive region 104 is an area that does not include such operable transistors. The unit cell transistors 200 of the MOSFET 100 are formed in the active region 102. The location of one unit cell 200 is shown by a box 200 in FIG. 2B to provide context.

The active region 102 may generally correspond to the area under the source metal pattern 123 in some embodiments. The inactive region 104 includes a gate pad portion 106 and a termination portion 108. The gate pad portion 106 of the inactive region 104 may approximately correspond to the portion of the semiconductor layer structure that is underneath the gate pad 132. The termination portion 108 of the inactive region 104 may extend around a periphery of the MOSFET 100 and may include one or more termination structures such as guard rings and/or a junction termination extension that can reduce electric field crowding that may occur around the edge of the device. The termination structures (shown as guard rings 109) may spread out the electric fields along the periphery of the MOSFET 100, reducing electric field crowding. The edge termination structures may serve to increase the reverse blocking voltage at which a phenomenon known as “avalanche breakdown” occurs where an increasing electric field result in runaway generation of charge carriers within the semiconductor device, resulting in a sharp increase in current that may damage or even destroy the device.

As is further shown in FIG. 2B, a gate electrode pattern 130 may be provided that includes a gate pad 132, a plurality of gate fingers 134, and one or more gate buses 136 that electrically connect the gate fingers 134 to the gate pad 132. The gate pad 132 of the gate electrode pattern 130 may be underneath the gate bond pad 120 in the gate pad portion 106 of the inactive region 104, and the gate fingers 134 may extend (e.g., horizontally) across the active region 102. An insulating layer (not shown) may cover the gate fingers 134 and gate bus(es) 136. The source metal pattern 123 may be provided over the gate fingers 134 and insulating layer, with the source contacts of the source metal layer contacting corresponding source regions in the semiconductor layer structure in openings between the gate fingers 134.

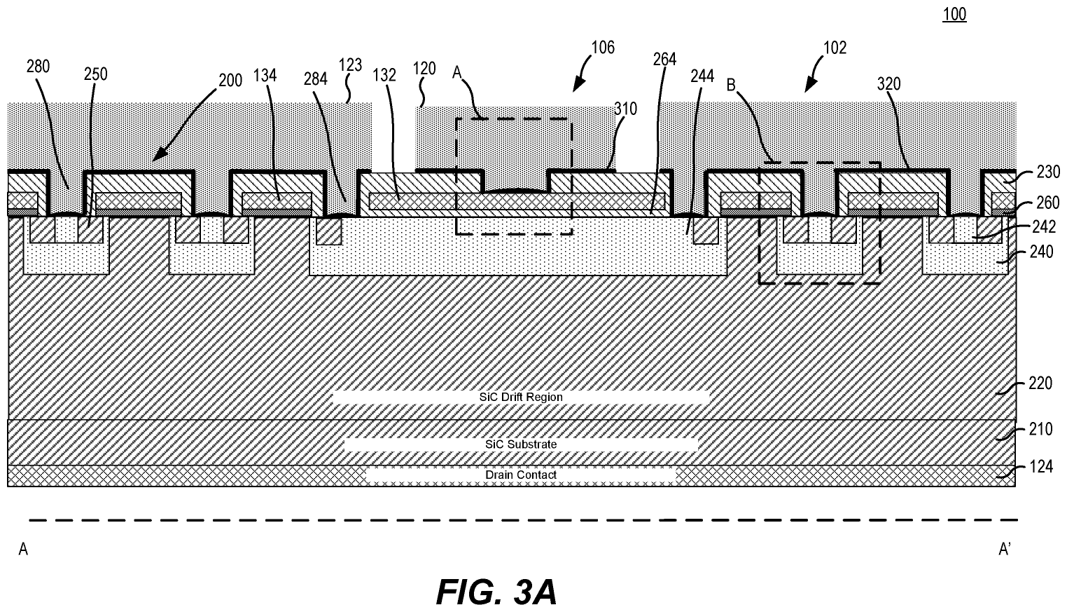

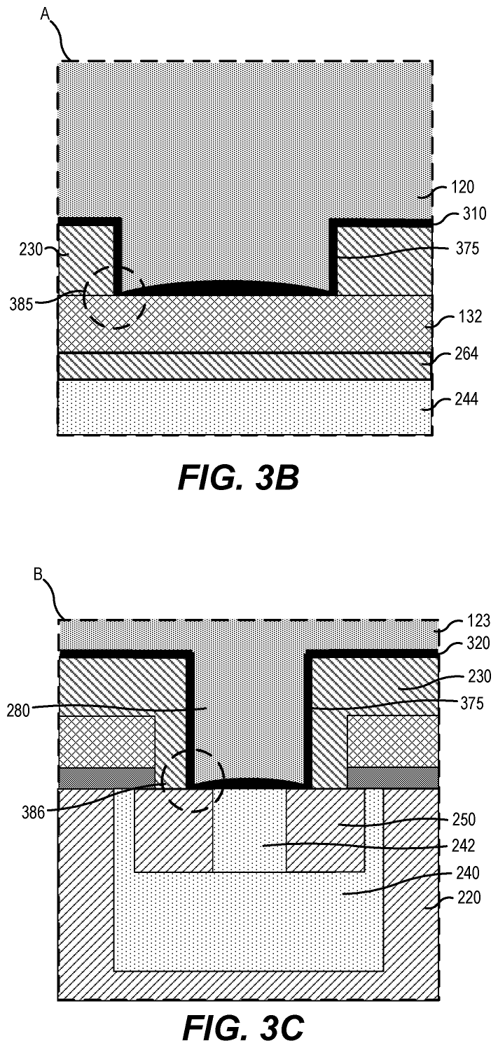

FIG. 3A is a schematic cross-sectional diagram taken along the line A-A′ of FIG. 2B that illustrates the unit cell structure in an active region, and the gate pad in an inactive region, of a conventional device. FIG. 3B is a schematic cross-sectional diagram of portion A of FIG. 3A. FIG. 3C is a schematic cross-sectional diagram of portion B of FIG. 3A.

Referring to FIG. 3A, the MOSFET device 100 may include a unit cell 200 that is part of the active region 102 of MOSFET 100. The unit cell 200 may be one of a plurality of unit cells 200 that are electrically disposed in parallel.

The power MOSFET 100, and hence the unit cell 200, may include an n-type wide band-gap semiconductor substrate 210. The substrate 210 may comprise, for example, a single crystal 4H silicon carbide semiconductor substrate. The substrate 210 may be heavily-doped with n-type impurities (i.e., an n⁺ silicon carbide substrate). The impurities may comprise, for example, nitrogen or phosphorous. The doping concentration of the substrate 210 may be, for example, between 1×10¹⁸ atoms/cm³ and 1×10²′ atoms/cm³, although other doping concentrations may be used. The substrate 210 may be any appropriate thickness (e.g., between 100 and 500 microns thick).

A lightly-doped n-type (n) silicon carbide drift region 220 may be provided on the substrate 210. The n-type silicon carbide drift region 220 may be formed by, for example, epitaxial growth on the silicon carbide substrate 210. The n-type silicon carbide drift region 220 may have, for example, a doping concentration of 1×10¹⁶ to 5×10¹⁷ dopants/cm³. The n-type silicon carbide drift region 220 may be a thick region, having a vertical height above the substrate 210 of, for example, 3-100 microns. An upper portion of the n-type silicon carbide drift region 220 may comprise an n-type silicon carbide current spreading layer in some embodiments that is more heavily doped than the lower portion of the n-type silicon carbide drift region 220.

An upper portion of the n-type silicon carbide drift region 220 may be doped p-type by ion implantation to form p-wells 240. The p-wells 240 may have a doping concentration of, for example, between 5×10¹⁶/cm³ and 5×10¹⁹/cm³. An upper portion 242 of each p-well 240 may be more heavily doped with p-type dopants. The upper portion 242 of each p-well 240 may have a doping concentration of, for example, between 2×10¹⁸/cm³ and 1×10²⁰/cm³. The p-wells 240 (including the more heavily-doped upper portions 242 thereof) may be formed by ion implantation. As is known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer to a certain depth.

In the active region 102, heavily-doped (n⁺) n-type silicon carbide source regions 250 may be formed in upper portions of the p-wells 240 directly adjacent and contacting the more heavily doped portions 242 of the p-wells 240. The n-type source regions 250 may also be formed by ion implantation. The heavily-doped (n⁺) n-type silicon carbide regions 250 act as source regions for the unit cell transistor 200. The drift region 220 and the substrate 210 together act as a common drain region for the unit cell transistor 200.

The n-type silicon carbide substrate 210, n-type silicon carbide drift region 220, the p-wells 240, 242 and the n-type source regions 250 formed therein may together comprise a semiconductor layer structure of the MOSFET device 100.

A gate insulating pattern 260 may be formed on the upper surface of the semiconductor layer structure over the exposed portions of the drift region 220 between the p-wells 240 and n-type source regions 250 and extending onto the edges of the p-wells 240 and n-type source regions 250. The gate insulating pattern 260 may comprise, for example, a silicon oxide layer, although other insulating materials may be used. A gate finger 134 is formed on the gate insulating pattern 260. It will be appreciated that the gate finger 134 may be part of a continuous gate electrode pattern 130 (see FIG. 2B) that includes a gate pad 132, a plurality of gate fingers 134, and one or more gate buses 136. In some embodiments, this gate electrode pattern 130 may comprise, for example, a semiconductor pattern (e.g., polysilicon) and/or a metal gate pattern.

Source contacts 280 may be formed on the n-type source regions 250 and the more heavily-doped portions 242 of the p-wells. As described above with reference to FIGS. 2A-2B, the source contacts 280 may be part of a continuous source metal pattern 123 that extends across the upper surface of the silicon carbide semiconductor layer structure. The remainder of the source metal pattern 123 (as well as the insulating layer that electrically isolates the gate fingers 270 from the source metal pattern 123) is not shown in FIG. 3A to simplify the drawing. The source contacts 280 may comprise, for example, metals such as nickel, titanium, tungsten or aluminum, or alloys or thin layered stacks of these or similar materials. As described above, a drain contact 124 may be formed on the lower surface of the substrate 210. The drain contact 124 may comprise, for example, similar materials to the source contact 280, as this forms an ohmic contact to the silicon carbide substrate. Current may flow from the n-type source regions 250 through the drift region 220 that is underneath the gate finger 134 when a voltage is applied to the gate finger 134.

While the MOSFET 100 is illustrated as an n-type device with the source contacts 280 on an upper surface thereof and the drain contact 124 on the bottom surface thereof, it will be appreciated that in p-type devices these locations are reversed. Accordingly, in portions of the descriptions below (including the claims) the source contacts and drain contacts may generically refer to either a source contact or a drain contact.

As illustrated in FIG. 3A, in the gate pad portion 106 of the inactive region, a p-well 244 extends underneath most or all of the gate pad portion 106 of the inactive region. The p-well 244 may extend for a significant distance in each horizontal direction underneath the gate pad portion 106, such as a distance of between 100-300 microns in each direction. A field insulating layer 264 is formed on the p-well 244 in the gate pad portion 106 of the inactive region 104. In some embodiments, the field insulating layer 264 may have a thickness of, for example, 600-800 nanometers in the vertical direction (i.e., in a direction perpendicular to the major surfaces of the substrate 210). A gate pad 132 is formed on the field insulating layer 264. As discussed above with reference to FIG. 2B, the gate pad 132 and gate fingers 134 may be part of a continuous gate electrode pattern 130.

In some embodiments, an additional source contact 284 may penetrate the field insulating layer 264 to contact the p-well 244. The additional source contact 284 may assist in managing a displacement current of the MOSFET device 100, as discussed in U.S. patent application Ser. No. 15/699,149, to Zhang, et al. entitled “Power Switching Devices with DV/DT Capability and Methods of Making such Devices,” filed on Sep. 8, 2017, the entire contents of which are included by reference herein. In some embodiments, the additional source contact 284 may be omitted.

An isolation layer 230 may be formed on the gate fingers 134 and/or the gate pad 132. The isolation layer 230 may serve to isolate the gate electrode pattern 130 (including the gate fingers 134 and the gate pad 132) from the source metal pattern 123 (including the source contacts 280 and the additional source contacts 284.

A gate barrier layer 310 may be disposed between the gate bond pad 120 and the gate pad 132. The gate barrier layer 310 may serve as a metallization barrier layer and/or an adhesion layer. Similarly, a source barrier layer 320 may be disposed between the source contact 280 and the source/drain region 250 and/or the additional source contact 284 and the p-well 244. The gate barrier layer 310 and/or the source barrier layer 320 may reduce and/or prevent a diffusion of metal from the respective contact into the underlying material over which the barrier layer is placed. For example, the gate barrier layer 310 may reduce a diffusion of metal materials from the metal of the gate bond pad 120 to the polysilicon of the gate pad 132. Elements that diffuse into the polysilicon may further diffuse into gate oxide and/or active areas, damaging the performance of the MOSFET device 100.

Referring to FIGS. 3B and 3C, in a conventional device the gate contacts and/or the source contacts are formed by etching a portion of the device (e.g., isolation layer 230) to form a contact hole 375. The barrier layer (e.g., gate barrier layer 310 and/or source barrier layer 320) may be formed within the contact hole 375. The metal for the contact may then be formed on the barrier layer. However, due to a step coverage associated with the formation of the barrier layer, corners of the contact hole 375 may have poor coverage. For example, referring to FIG. 3B, a region 385 of the gate barrier layer 310 may be thin between the gate bond pad 120 and the gate pad 132 at a corner of the contact hole 375. Similarly, referring to FIG. 3C, a region 386 of the source barrier layer 320 may be thin between the source contact 280 and the source region 250 at a corner of the contact hole 375. Due to the thinness of corner regions 385, 386 of the source and gate contact holes 375, conventional devices may be susceptible to diffusion from the metal layers of the gate bond pad 120 and/or the source contact 280.

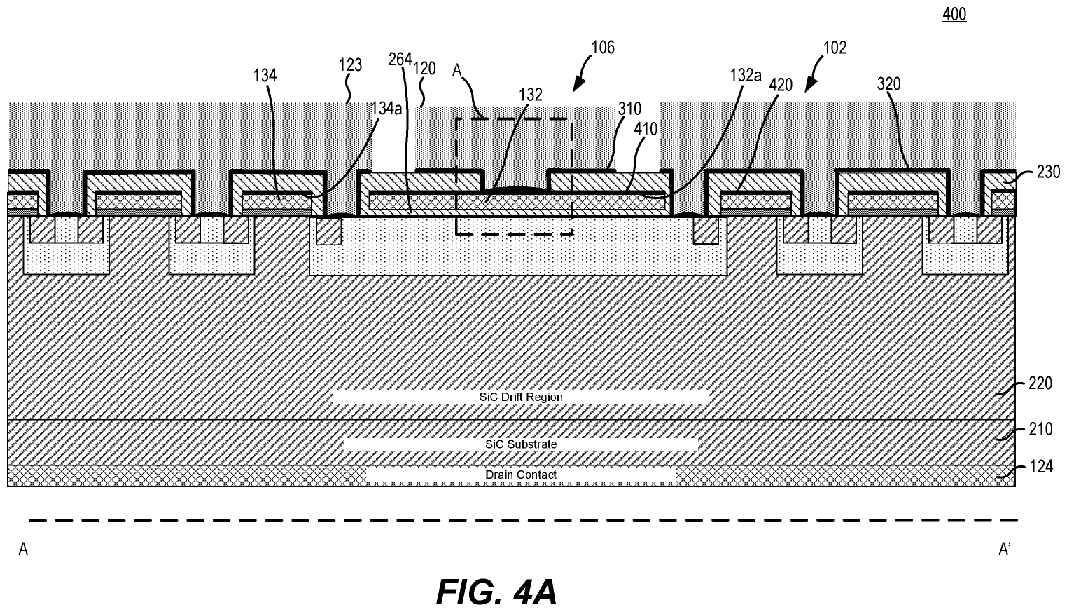

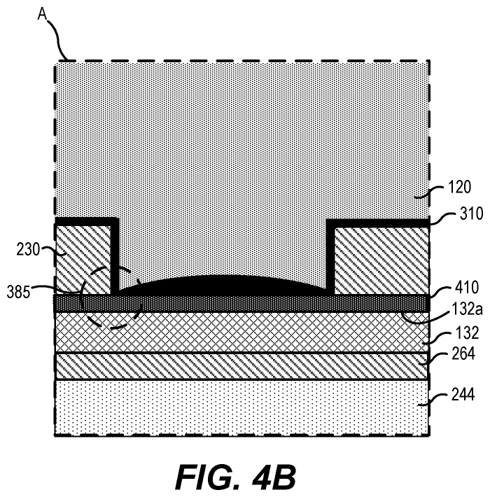

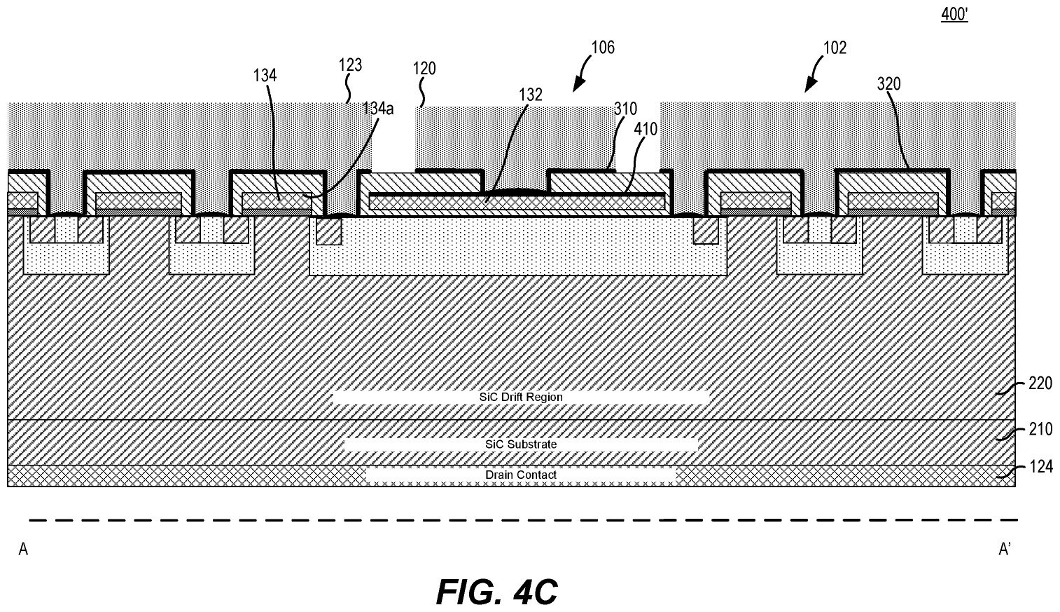

FIG. 4A illustrates a semiconductor device 400 according to some embodiments described herein. FIG. 4B is a schematic cross-sectional diagram of portion A of FIG. 4A. FIG. 4C illustrates an additional semiconductor device 400′ according to some embodiments described herein. A description of those elements of FIGS. 4A-4C that are the same or similar to those of FIGS. 3A-3C will be omitted for brevity. Accordingly, the description of FIGS. 4A-4C will focus on differences with those devices previously described.

Referring to FIGS. 4A and 4B, a MOSFET device 400 according to some embodiments described herein may include additional barrier layers as compared to a conventional device. For example, the MOSFET device 400 may include an auxiliary gate pad barrier layer 410 and an auxiliary gate electrode barrier layer 420.

The auxiliary gate pad barrier layer 410 may be formed on the gate pad 132 and may be on, and in some embodiments cover, an upper surface 132a of the gate pad 132. In FIG. 4B, the auxiliary gate pad barrier layer 410 is illustrated with a separate shading to assist in identifying it with respect to the gate barrier layer 310, but this separate shading is not intended to limit the configuration of either the auxiliary gate pad barrier layer 410 or the gate barrier layer 310. The auxiliary gate pad barrier layer 410 may be provided in addition to the gate barrier layer 310. As a result, a barrier layer will exist above (e.g., in the form of the gate barrier layer 310) and below (e.g., in the form of the auxiliary gate pad barrier layer 410) the isolation layer 230 that isolates the device from the gate bond pad 120. In some embodiments, the gate barrier layer 310 may be on and/or contact the auxiliary gate pad barrier layer 410 in a portion of the MOSFET device 400 that is between (e.g., in a vertical direction) the gate bond pad 120 and the gate pad 132. In some embodiments, the isolation layer 230 may be between the auxiliary gate pad barrier layer 410 and the gate barrier layer 310 and/or the gate bond pad 120. In some embodiments, the isolation layer 230 may be on a top surface of a portion of the auxiliary gate pad barrier layer 410 and on a sidewall of the gate barrier layer 310.

The presence of the auxiliary gate pad barrier layer 410 may improve the barrier layer coverage at the bottom corner region 385 between the gate bond pad 120 and the gate pad 132. For example, the auxiliary gate pad barrier layer 410 may have a width in a direction parallel to a top surface of the substrate 210 (e.g., in a horizontal direction) that exceeds that of the portion of the gate barrier layer 310 that is between the auxiliary gate pad barrier layer 410 and the bottom portion of the gate bond pad 120 (e.g., the portion of the gate barrier layer 310 that extends between the sidewalls of the contact hole connecting the gate bond pad 120 to the gate pad 132). Thus even if the deposition of the gate barrier layer 310 at the bottom corner region 385 is not ideal, the layer below (here the gate pad 132) may be protected from any elements in the contact metal.

An auxiliary gate electrode barrier layer 420 may also be provided on the gate fingers 134 in the active region 102 of the MOSFET device 400. As with the auxiliary gate pad barrier layer 410, the auxiliary gate electrode barrier layer 420 can serve the purpose of a diffusion barrier to elements that may diffuse at the gate electrode interface with materials on top of it, improve the layer conductivity, and/or enhance the adhesion of the gate finger 134 to dielectric layers on top of it.

When the auxiliary gate electrode barrier layer 420 is present, a barrier layer will exist below (e.g., in the form of the auxiliary gate electrode barrier layer 420) and above (e.g., in the form of source barrier layer 320) the isolation layer 230 that isolates the gate finger 134 from the source metal pattern 123. In some embodiments, auxiliary gate electrode barrier layer 420 may be between an upper surface 134a of the gate finger 134 and the isolation layer 230.

The auxiliary gate pad barrier layer 410 and/or the auxiliary gate electrode barrier layer 420 may be applied in a variety of methods, to produce a continuous or contiguous layer from 0.5 nm to 500 nm thick. In some embodiments, the thickness of the auxiliary gate pad barrier layer 410 and/or the auxiliary gate electrode barrier layer 420 may be substantially uniform. The auxiliary gate pad barrier layer 410 and/or the auxiliary gate electrode barrier layer 420 may include titanium (Ti), titanium nitride (TiN), tantalum (Ta), tantalum nitride (TaN), as well as other metal nitrides and/or intermetallics, including, for example cobalt (Co), ruthenium (Ru), and the like. The auxiliary gate pad barrier layer 410 and/or the auxiliary gate electrode barrier layer 420 may be a single layer (such as TiN, TaN, or similar materials which have good thermodynamic stability and are electrically conductive), or a multilayer stack of various elemental or compound materials, in various stacking sequences. Accordingly, though FIGS. 4A and 4B illustrate a single layer for the auxiliary gate pad barrier layer 410 and the auxiliary gate electrode barrier layer 420, the illustrated structure is intended to also represent structures comprising multiple layers. In some embodiments, conducting oxides can be used where adhesion to a dielectric layer is important. As will be understood by one of ordinary skill in the art, the material used will depend on the processing and application. The use of the auxiliary gate pad barrier layer 410 and/or the auxiliary gate electrode barrier layer 420 may be applied as required to improve the properties of diffusion barrier, conductivity, and/or adhesion.

In some embodiments, a material and/or configuration used for the auxiliary gate pad barrier layer 410 may differ from a material and/or configuration used for the auxiliary gate electrode barrier layer 420. In some embodiments, a material and/or configuration used for the auxiliary gate pad barrier layer 410 may differ from a material and/or configuration used for gate barrier layer 310. In some embodiments, a material and/or configuration used for the auxiliary gate electrode barrier layer 420 may differ from a material and/or configuration used for gate barrier layer 310.

In some embodiments, the auxiliary gate pad barrier layer 410 may be present and the auxiliary gate electrode barrier layer 420 may be omitted. For example, FIG. 4C illustrates a MOSFET device 400′ in which the auxiliary gate electrode barrier layer 420 is not present.

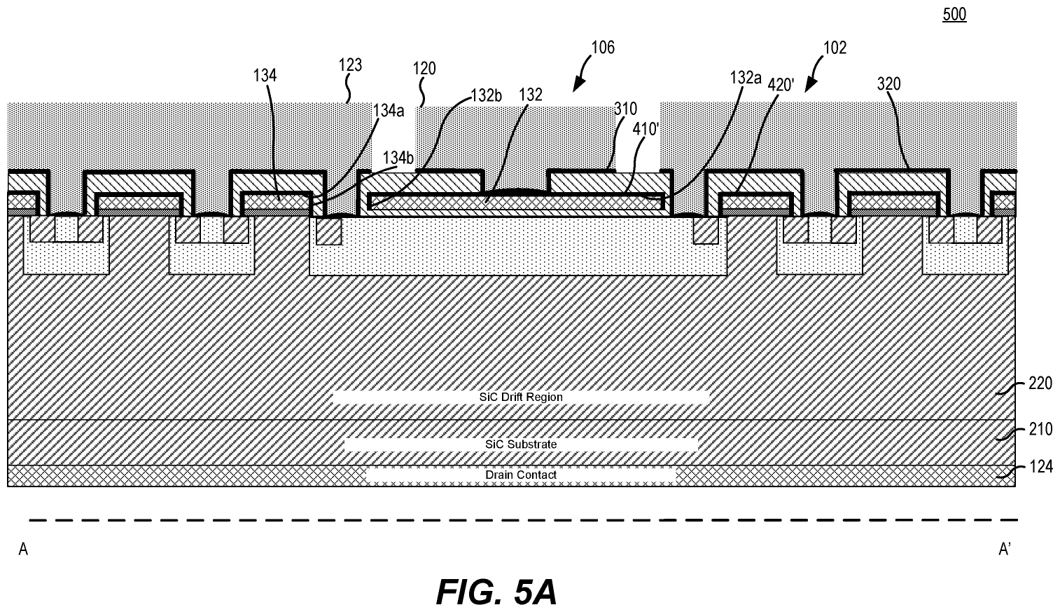

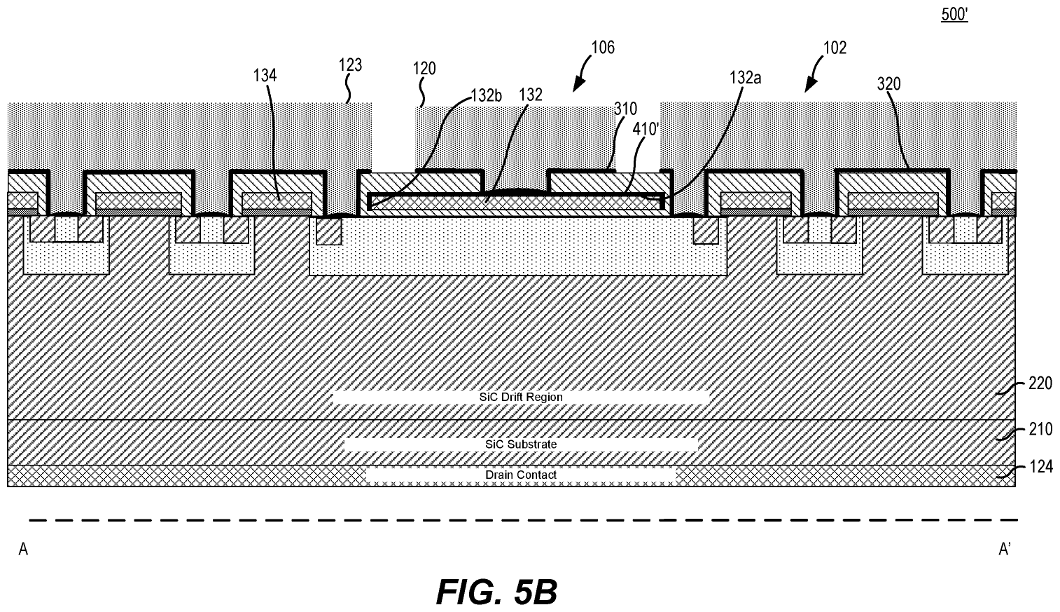

FIGS. 5A and 5B illustrate additional semiconductor devices according to some embodiments described herein. A description of those elements of FIGS. 5A and 5B that are the same or similar to those of previously-described figures will be omitted for brevity. Accordingly, the description of FIGS. 5A and 5B will focus on differences with those devices previously described.

Referring to FIG. 5A, in a MOSFET device 500 according to some embodiments, an auxiliary gate pad barrier layer 410′ may extend on a top surface 132a and on one or more sidewalls 132b of the gate pad 132. Thus the auxiliary gate pad barrier layer 410′ may extend continuously on top and side surfaces of the gate pad 132.

Similarly, an auxiliary gate electrode barrier layer 420′ may extend onto one or more sidewalls 134b of the gate finger 134. Thus the auxiliary gate electrode barrier layer 420′ may extend continuously on top and side surfaces of the gate finger 134.

The use of the auxiliary gate pad barrier layer 410′ and/or the auxiliary gate electrode barrier layer 420′ may increase a diffusion barrier of the gate pad 132 and/or the gate finger 134. In addition, the auxiliary gate pad barrier layer 410′ and/or the auxiliary gate electrode barrier layer 420′ may improve adhesion with the respective gate pad 132 and/or the gate finger 134.

As previously described, in some embodiments, the auxiliary gate pad barrier layer 410′ may be present and the auxiliary gate electrode barrier layer 420′ may be omitted. For example, FIG. 5B illustrates a MOSFET device 500′ in which the auxiliary gate electrode barrier layer 420′ is not present.

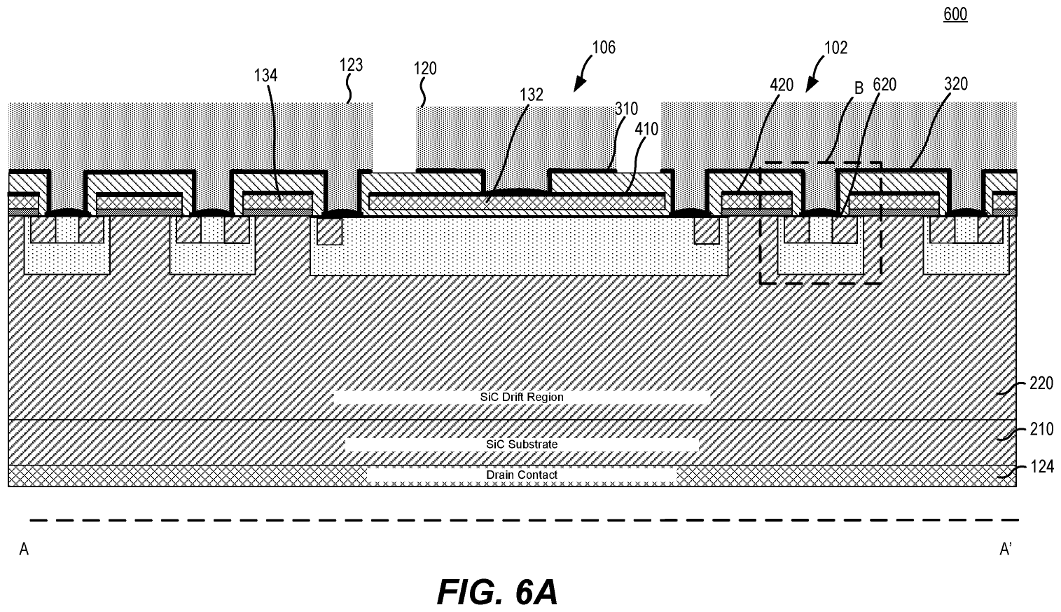

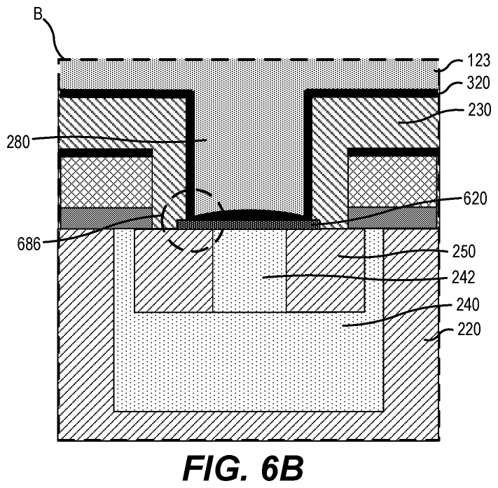

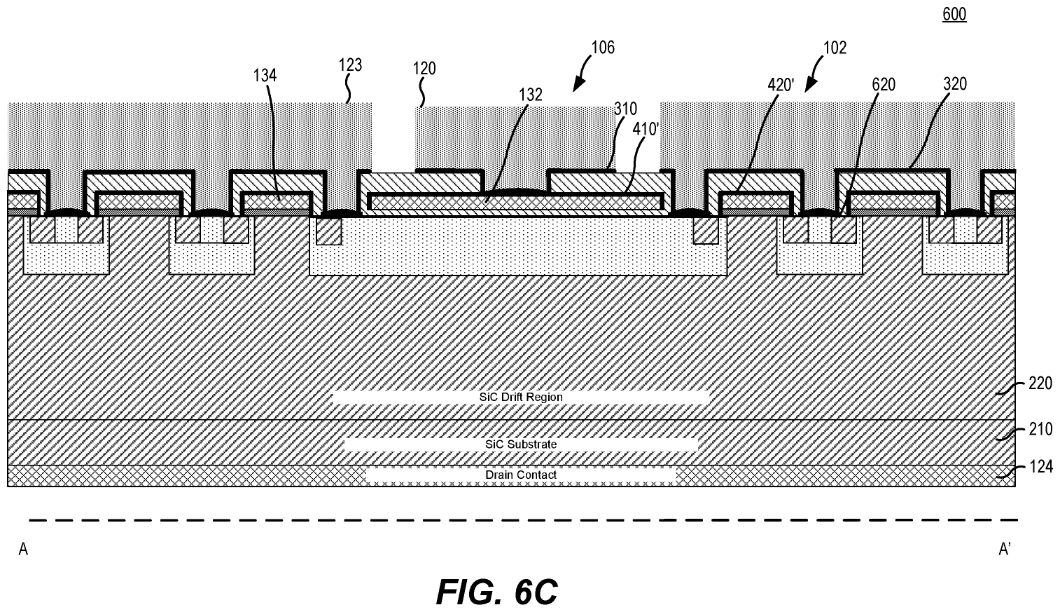

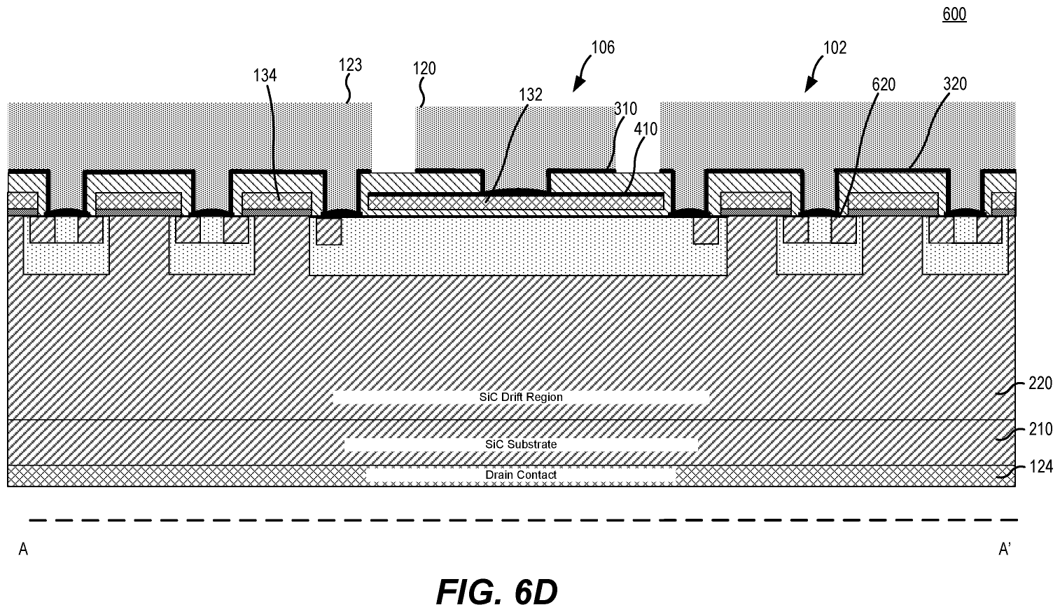

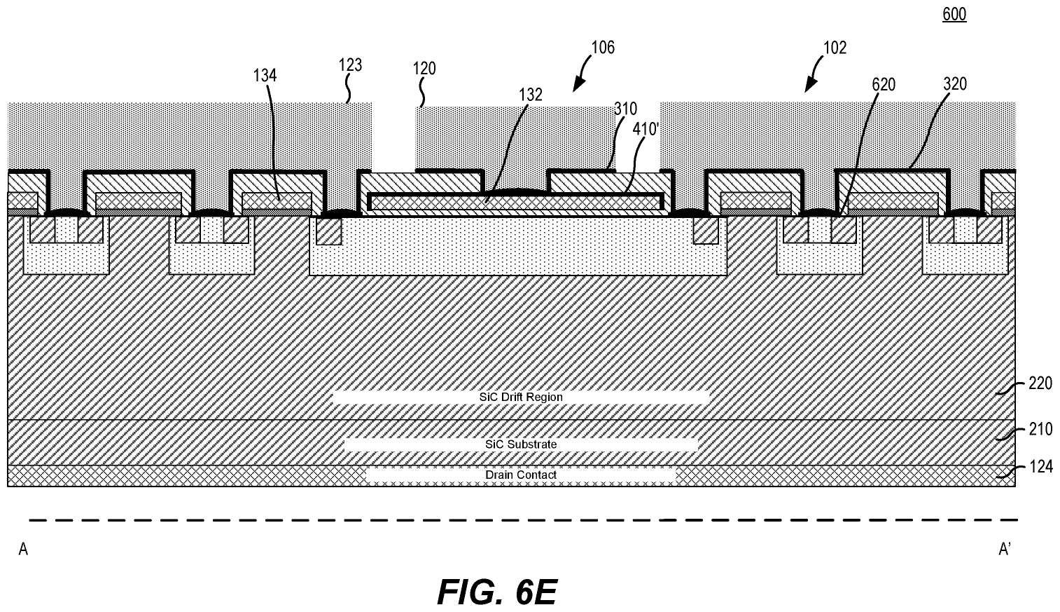

FIG. 6A illustrates an additional semiconductor device 600 according to some embodiments described herein. FIG. 6B is a schematic cross-sectional diagram of portion B of FIG. 6A. FIGS. 6C to 6E illustrate additional semiconductor devices according to some embodiments described herein. A description of those elements of FIGS. 6A to 6E that are the same or similar to those of previously-described figures will be omitted for brevity. Accordingly, the description of FIGS. 6A to 6E will focus on differences with those devices previously described.

Referring to FIGS. 6A and 6B, a MOSFET device 600 may include an auxiliary source barrier layer 620. The auxiliary source barrier layer 620 may be formed on the semiconductor structure and may be formed on the n-type source regions 250 and/or the more heavily-doped portions 242 of the p-wells. The auxiliary source barrier layer 620 may be provided in addition to the source barrier layer 320. In FIG. 6B, the auxiliary source barrier layer 620 is illustrated with a separate shading to assist in identifying it with respect to the source barrier layer 320, but this separate shading is not intended to limit the configuration of either the auxiliary source barrier layer 620 or the source barrier layer 320. In some embodiments, the source barrier layer 320 may be on and/or contact the auxiliary source barrier layer 620 in a portion of the MOSFET device 600 that is between the source contact 280 and the semiconductor structure including the heavily-doped n-type source regions 250 and the more heavily-doped portions 242 of the p-wells.

As illustrated in FIG. 6B, in some embodiments the auxiliary source barrier layer 620 may extend beyond the source barrier layer 320 that is on a sidewall of the source contact 280. In some embodiments, a portion of the isolation layer 230 may be between a portion of the auxiliary source barrier layer 620 and the source barrier layer 320. The use of the auxiliary source barrier layer 620 may provide additional diffusion protection between the source contact 280 and the semiconductor structure including the n-type source regions 250 and/or the more heavily-doped portions 242 of the p-wells. For example, region 686 at the corner of the source contact 280 may be reinforced through the use of the auxiliary source barrier layer 620.

Referring to FIG. 6A, the MOSFET device 600 may include the use of the auxiliary source barrier layer 620 in conjunction with the auxiliary gate pad barrier layer 410 and/or the auxiliary gate electrode barrier layer 420 illustrated in FIGS. 4A to 4C, though the present disclosure is not limited thereto. In some embodiments, the auxiliary source barrier layer 620 may be used independently of one or more of the auxiliary gate pad barrier layer 410 and the auxiliary gate electrode barrier layer 420.

FIG. 6C illustrates an embodiment in which the auxiliary source barrier layer 620 is used in conjunction with the auxiliary gate pad barrier layer 410′ and the auxiliary gate electrode barrier layer 420′ discussed herein with respect to FIGS. 5A and 5B. FIGS. 6A to 6C illustrate the auxiliary source barrier layer 620 used together with the auxiliary gate electrode barrier layer 420, however the embodiments described herein are not limited thereto. FIGS. 6D and 6E illustrate the use of the auxiliary source barrier layer 620 with the auxiliary gate pad barrier layers 410, 410′, without the presence of an auxiliary gate electrode barrier layer 420 420′.

Therefore, it will be understood that the auxiliary gate pad barrier layer 410, the auxiliary gate pad barrier layer 410′, the auxiliary gate electrode barrier layer 420, the auxiliary gate electrode barrier layer 420′, and the auxiliary source barrier layer 620 may be used independently of one another and in various combinations without deviating from the scope of the embodiments described herein.

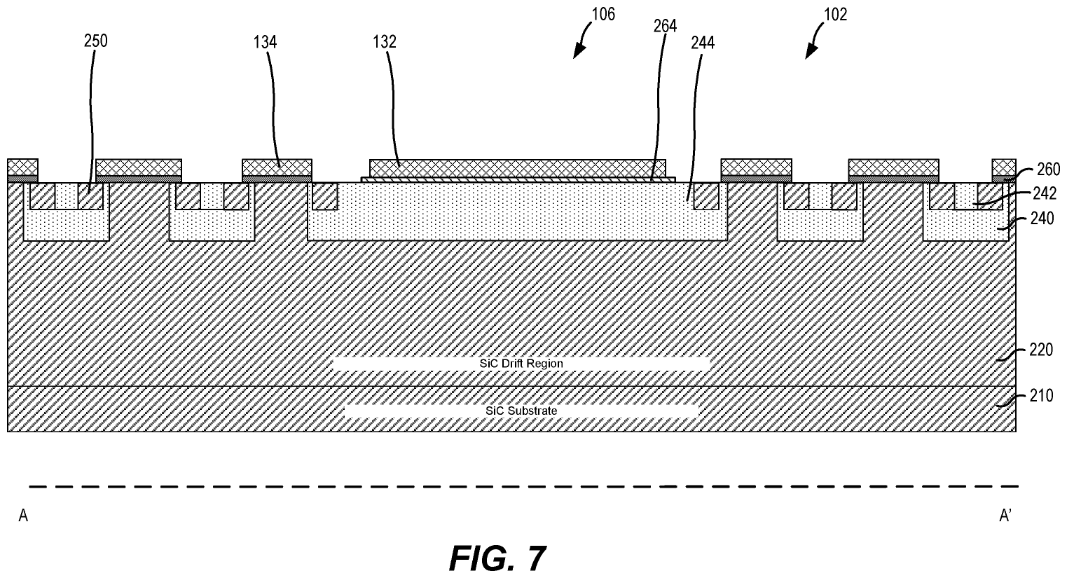

FIGS. 7-12 illustrate methods of manufacturing semiconductor devices according to embodiments described herein.

Referring to FIG. 7, a substrate 210 is provided and a drift region 220 is formed on the substrate 210 via epitaxial growth. In some embodiments, the substrate 210 is a heavily-doped (n⁺) n-type silicon carbide and the drift region 220 is a lightly-doped (n) silicon carbide drift region 220. In some embodiments, an n-type silicon carbide current spreading layer may be formed that comprises the upper portion of the drift layer 220.

P-wells 240 may be formed in what will be the active region 102 of the final device and p-wells 244 may be formed in what will be the inactive region 106 of the final device. In the active region 102, an upper portion 242 of each p-well 240 may be more heavily doped with p-type dopants, and heavily-doped (n⁺) n-type silicon carbide source regions 250 may be formed in upper portions of the p-wells 240 directly adjacent and contacting the more heavily doped portions 242 of the p-wells 240. The heavily-doped (n⁺) n-type silicon carbide regions 250 act as source regions for the unit cell transistor 200. In some embodiments, ion implantation may be used to form the p-wells 240, 244 and the n-type source regions 250.

In the active region 102, a gate insulating layer may be formed on the upper surface of the semiconductor layer structure. The gate insulating layer may be patterned and etched to form gate insulating patterns 260 over the exposed portions of the drift region 220 and extending onto the edges of the p-wells 240 and n-type source regions 250. In the inactive region 106, a field insulating layer 264 may be formed on the p-well 244.

A conductive material, such as polysilicon, may be formed on the field insulating layer 264 and the gate insulating patterns 260. The conductive material may be patterned and etched to form the gate pad 132 and the gate fingers 134. The gate pad 132 and the gate fingers 134 may be electrically coupled to one another.

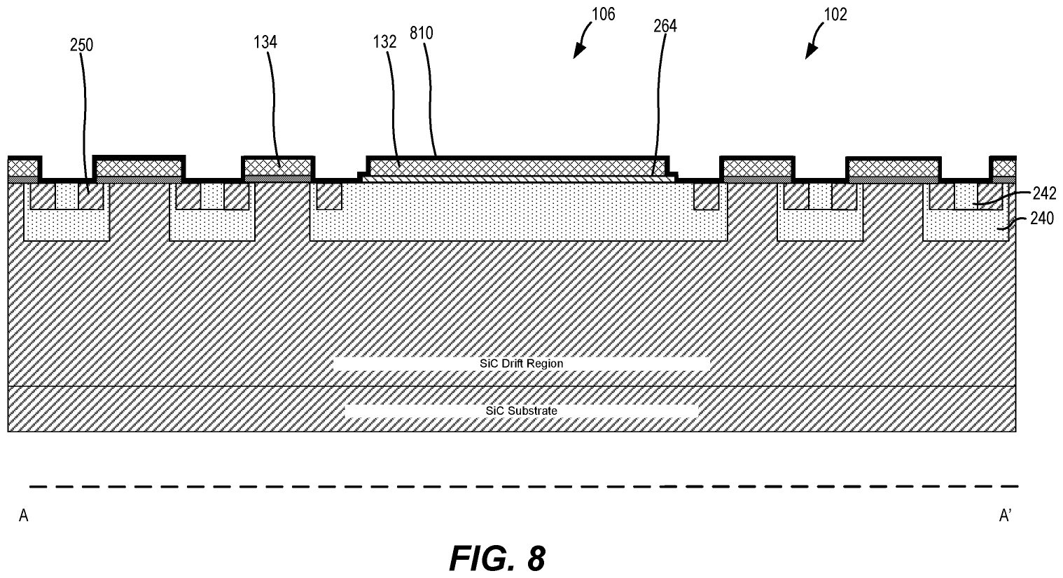

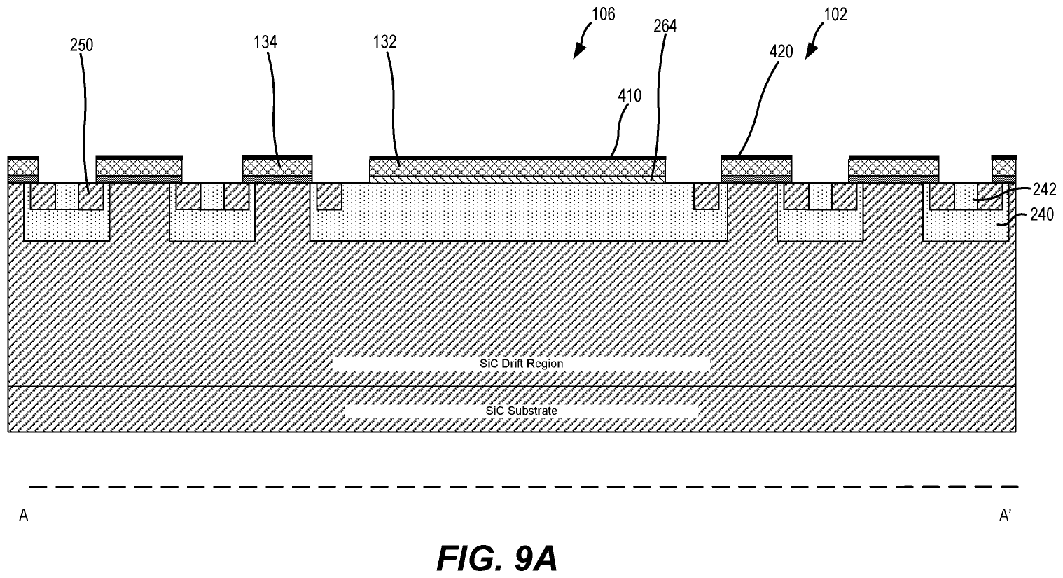

Referring to FIG. 8, an auxiliary barrier layer 810 may be formed on the gate fingers 134 and gate pad 132. In some embodiments, the auxiliary barrier layer 810 may extend on respective sidewalls of the gate fingers 134 and the gate pad 132. In some embodiments, the auxiliary barrier layer 810 may be formed on the n-type source regions 250 and the more heavily-doped portions 242 of the p-wells.

The auxiliary barrier layer 810 may include titanium (Ti), titanium nitride (TiN), tantalum (Ta), tantalum nitride (TaN), as well as other metal nitrides and/or intermetallics, including, for example cobalt (Co), ruthenium (Ru), and the like. The auxiliary barrier layer 810 may be a single layer (such as TiN, TaN, or similar materials which have good thermodynamic stability and are electrically conductive), or a multilayer stack of various elemental or compound materials, in various stacking sequences. Accordingly, though FIG. 8 illustrates a single layer for the auxiliary barrier layer 810, the illustrated structure is intended to also represent structures comprising multiple layers.

Though illustrated as covering both the active area 102 and the inactive area 106, it will be understood the embodiments of the present disclosure are not limited to this configuration. In some embodiments, the auxiliary barrier layer 810 may only be formed in the inactive area 106. In other words, in some embodiments, the auxiliary barrier layer 810 may only be formed on the gate pad 132.

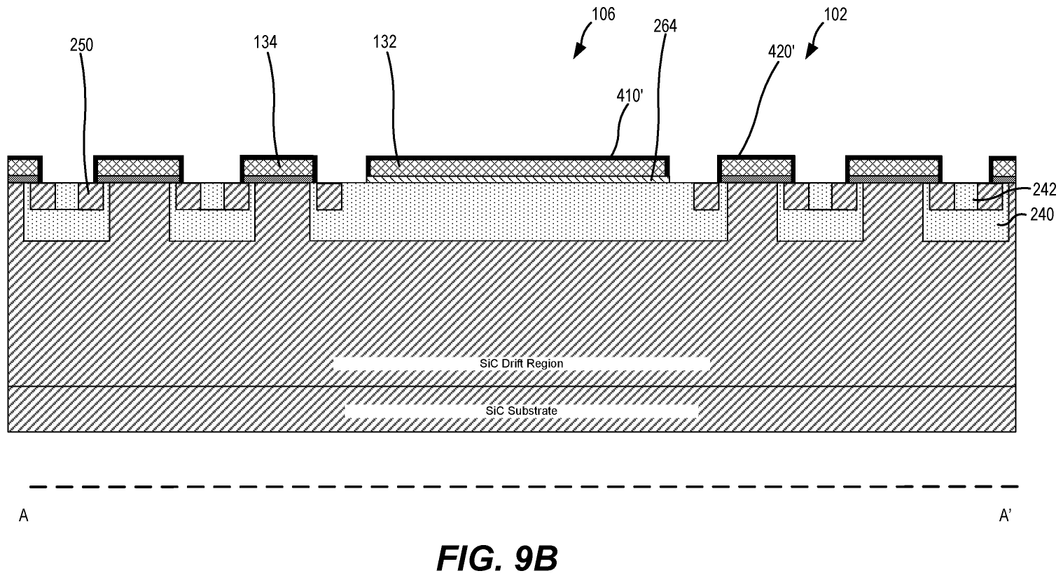

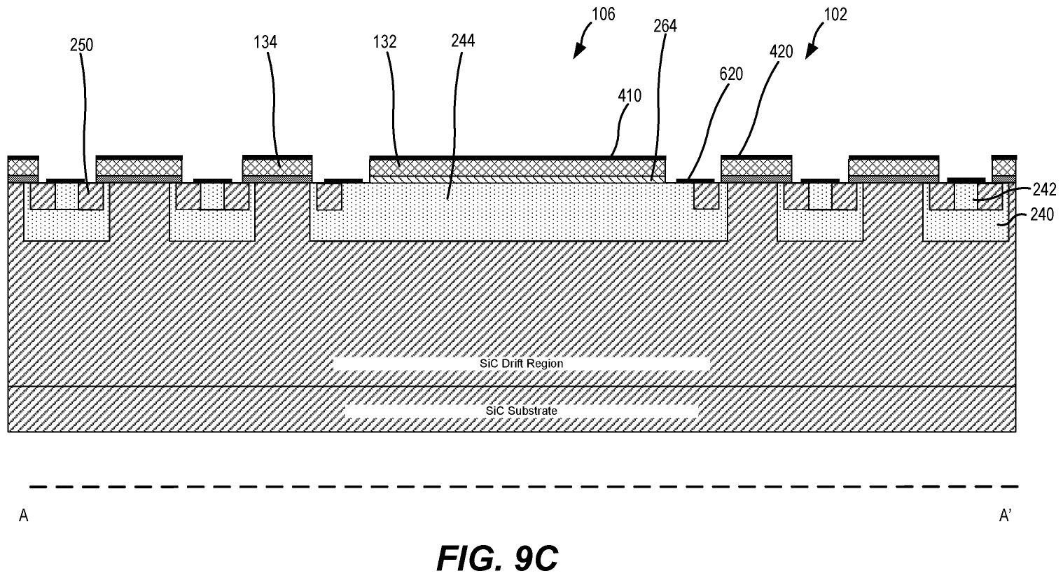

The auxiliary barrier layer 810 may then be patterned and etched using standard techniques to form auxiliary barrier layers according to various embodiments described herein. For example, referring to FIG. 9A, the auxiliary barrier layer 810 may be patterned and etched to remove all portions of the auxiliary barrier layer 810 except for over the gate pad 132 and the gate fingers 134. In this way, an auxiliary gate pad barrier layer 410 and an auxiliary gate electrode barrier layer 420, such as those illustrated in FIG. 4A may be formed. In some embodiments, portions of the field insulating layer 264 may be also be removed as part of forming the auxiliary gate pad barrier layer 410, but the embodiments described herein are not limited thereto.

Referring to FIG. 9B, the auxiliary barrier layer 810 may be alternatively patterned and etched to remove all portions of the auxiliary barrier layer 810 except for over the gate pad 132 and the gate fingers 134. As illustrated in FIG. 9B, the etching may be performed to leave the portions of the auxiliary barrier layer 810 on sidewalls of the gate pad 132 and the gate fingers 134. In this way, an auxiliary gate pad barrier layer 410′ and an auxiliary gate electrode barrier layer 420′, such as those illustrated in FIG. 5A may be formed.

In some embodiments, the auxiliary barrier layer 810, or another layer, may be patterned and etched to leave portions of the auxiliary barrier layer 810 on the n-type source regions 250, the more heavily-doped portions 242 of the p-wells, and/or p-well 244. In this way, auxiliary source barrier layers 620, such as those illustrated in FIG. 6A may be formed. FIG. 9C illustrates an embodiment in which the auxiliary barrier layer 810 is patterned and etched to form the auxiliary source barrier layer 620 along with the auxiliary gate pad barrier layer 410 and the auxiliary gate electrode barrier layer 420. FIG. 9D illustrates an embodiment in which the auxiliary barrier layer 810 is patterned and etched to form the auxiliary source barrier layer 620 along with the auxiliary gate pad barrier layer 410′ and the auxiliary gate electrode barrier layer 420′.

In some embodiments, an additional patterning step may be performed on the field insulating layer 264 to form the auxiliary source barrier layer 620. For example, referring back to FIG. 8, in some embodiments, portions of the field insulating layer 264 and the auxiliary barrier layer 810 may be patterned and etched to expose an upper surface of the n-type source regions 250, the more heavily-doped portions 242 of the p-wells, and/or p-well 244. Then additional barrier layer material may be deposited in the exposed area to form the auxiliary source barrier layer 620. In some embodiments, the barrier layer material used to form the auxiliary source barrier layer 620 may be the same as that used to form the auxiliary gate pad barrier layer 410 and the auxiliary gate electrode barrier layer 420, but the embodiments described herein are not limited thereto. Additional mechanisms for forming the auxiliary gate pad barrier layer 410, the auxiliary gate electrode barrier layer 420, and the auxiliary source barrier layer 620 will be recognized by those of ordinary skill in the art, and the embodiments described herein are not limited to those illustrated in the figures.

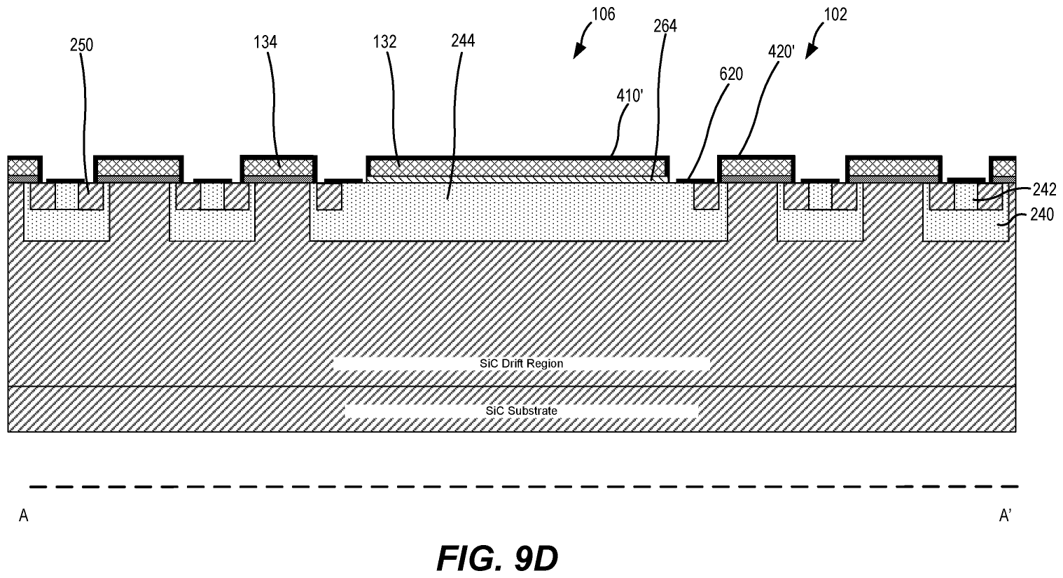

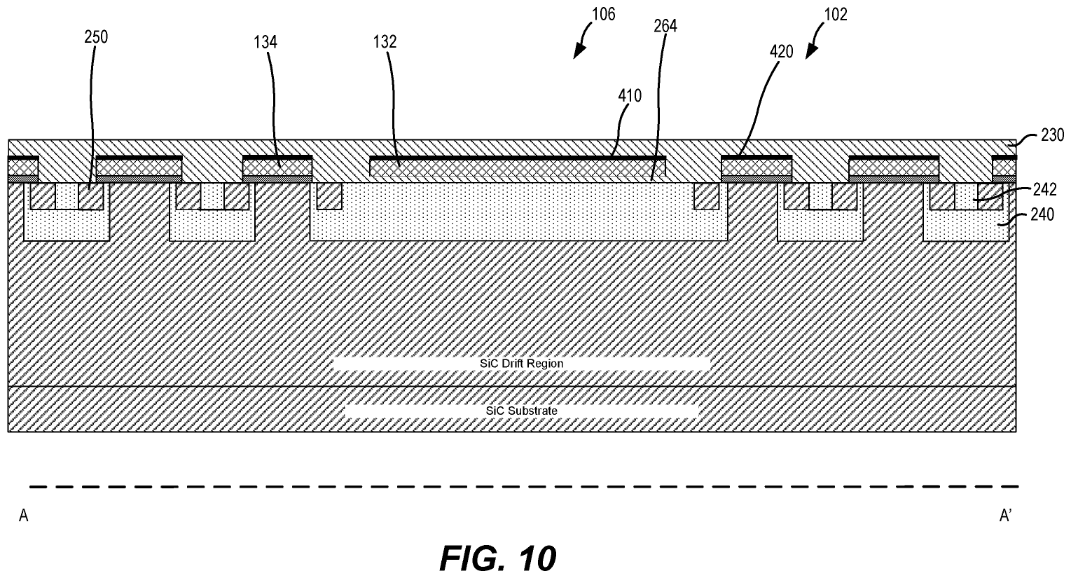

Following the formation of the auxiliary barrier layer, additional processing may be performed to create one or more of the MOSFET devices described herein. FIGS. 10-12 primarily focus on processes that form MOSFET device 400 illustrated with respect to FIG. 4A. However, it will be understood that the processing described herein could be altered mutatis mutandis to achieve additional embodiments of the devices described herein without limitation.

Referring to FIG. 10, an isolation layer 230 may be formed on the gate fingers 134, the gate pad 132, the field insulating layer 264, the auxiliary gate pad barrier layer 410, and the auxiliary gate electrode barrier layer 420. The isolation layer 230 may be an IMD (inter-metal dielectric) layer or an ILD (inter-layer dielectric) layer. In some embodiments, the isolation layer 230 may include a same or similar material as the field insulating layer 264, but the embodiments described herein are not limited thereto.

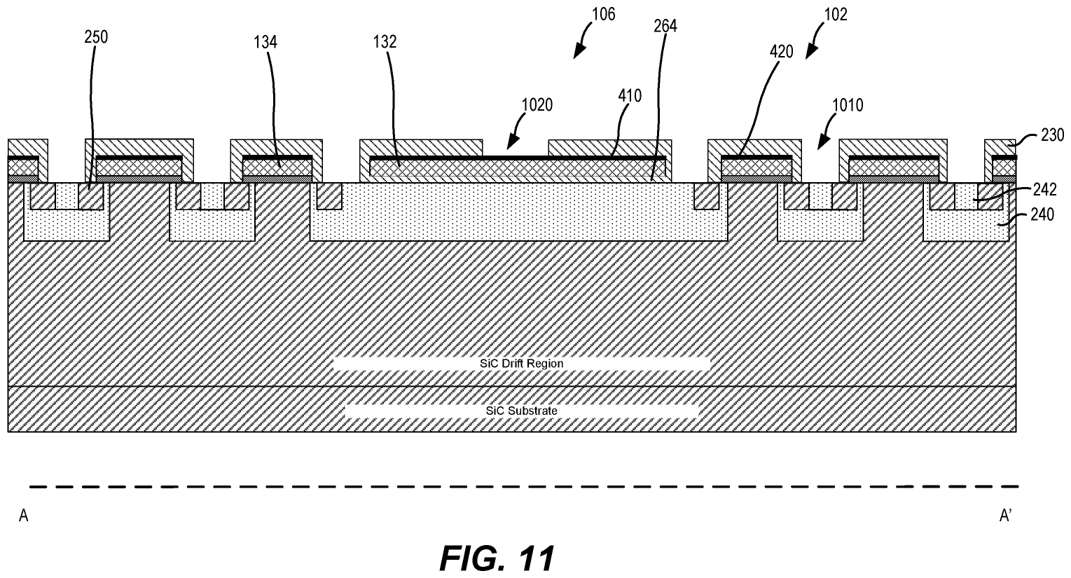

Referring to FIG. 11, the isolation layer 230 is patterned and etched to form contact holes 1010 for the source contacts and contact hole 1020 for the gate bond pad. The contact hole 1020 may expose portions of the auxiliary gate pad barrier layer 410. In some embodiments, the auxiliary gate pad barrier layer 410 may extend beyond sidewalls of the contact hole 1020. The contact holes 1010 may expose portions of the semiconductor structure, such as the n-type source regions 250 and/or the more heavily-doped portions 242 of the p-wells 240. In embodiments in which auxiliary source barrier layers 620 are present (see, e.g., FIGS. 9C and 9D), the contact holes 1010 may expose the auxiliary source barrier layers 620.

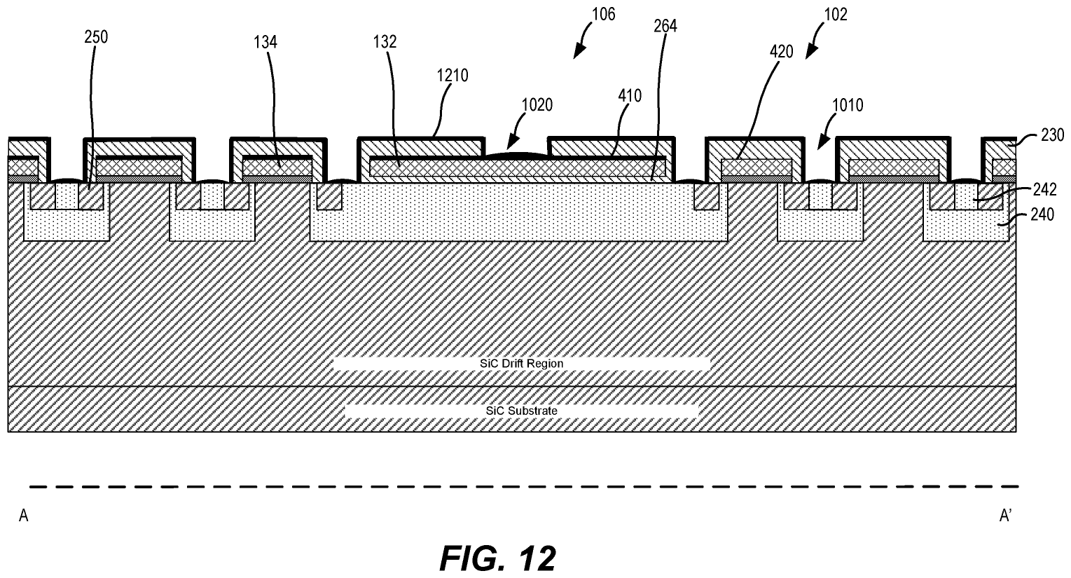

Referring to FIG. 12, barrier layer 1210 may be formed on the isolation layer 230 and within the contact holes 1010 and 1020. The barrier layer 1210 may be on sidewalls and bottoms of the contact holes 1010 and 1020. The barrier layer 1210 may also be formed on portions of the auxiliary gate pad barrier layer 410 exposed by the contact hole 1020. In embodiments in which auxiliary source barrier layers 620 are present (see, e.g., FIGS. 9C and 9D), the barrier layer 1210 may be formed on the auxiliary source barrier layers 620 exposed by the contact holes 1010.

Referring back to FIG. 4A, a metal contact layer may be formed on the active area 102 and the inactive area 104. The metal contact layer may be patterned and etched to form the gate bond pad 120 and the source metal pattern 123. The etching of the metal contact layer may also separate the barrier layer 1210 into the gate barrier layer 310 and the source barrier layer 320.

The power switching devices according to embodiments disclosed herein may provide significantly improved performance. By reducing a diffusion of materials into active regions of the device and/or increasing an adhesion between the metal layers and other conductive portions of the device, the overall structure of the device may be improved and defects may be reduced and/or eliminated.

It will be appreciated that the specific layer structure, doping concentrations, materials, conductivity types and the like that are shown in the figures and/or described herein are merely provided as examples to illustrate in detail the structure of a specific example embodiment. Thus, the specific details discussed below are not limiting to the present invention.

Herein, embodiments of the present invention are described with respect to cross-sectional diagrams that show one or two unit cells of a power switching devices. It will be appreciated that actual implementations will typically include a much larger number of unit cells. However, it will also be appreciated that the present invention is not limited to such devices, and that the claims appended hereto also cover MOSFETs and other power switching devices that comprise, for example, a single unit cell. Moreover, while the present disclosure focuses on silicon carbide devices, it will be appreciated that embodiments of the present invention may also have applicability to devices formed using other wide band-gap semiconductors such as, for example, gallium nitride, zinc selenide or any other II-VI or III-V wide band-gap compound semiconductors.

While some of the preceding figures illustrate the structure of a unit cell of an n-channel MOSFET, it will be appreciated that pursuant to further embodiments of the present invention, the polarity of each of the semiconductor layers in each device could be reversed so as to provide corresponding p-channel MOSFETs.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on,” “connected to,” or “coupled to” another element or layer, it can be directly on, connected or coupled to the other element or layer, or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device comprising:
a semiconductor layer structure comprising an active region and an inactive region, the active region comprising a plurality of unit cells and the inactive region comprising a gate pad on the semiconductor layer structure and a gate bond pad on and electrically connected to the gate pad;
an isolation layer between the gate pad and the gate bond pad; and
a barrier layer between the gate pad and the isolation layer.

2. The semiconductor device of claim 1, wherein the barrier layer is a first barrier layer, the semiconductor device further comprising:
a second barrier layer on the gate pad and on the first barrier layer,
wherein at least a portion of the isolation layer is between the first barrier layer and the second barrier layer.

3-4. (canceled)

5. The semiconductor device of claim 1, wherein the barrier layer comprises titanium (Ti) and/or tantalum (Ta).

6. The semiconductor device of claim 1, wherein the barrier layer is on a top surface and a sidewall of the gate pad.

7. The semiconductor device of claim 1, wherein the barrier layer is a first barrier layer, the semiconductor device further comprising:
a gate finger on the active region and electrically connected to the gate bond pad; and
a second barrier layer on the gate finger.

8. The semiconductor device of claim 7, wherein the second barrier layer is on a top surface and a sidewall of the gate finger.

9. The semiconductor device of claim 1, wherein the barrier layer is a first barrier layer, the semiconductor device further comprising:
a source contact on the semiconductor layer structure;
a second barrier layer on sidewalls and a bottom surface of the source contact; and
a third barrier layer between the semiconductor layer structure and the second barrier layer.

10. A semiconductor device comprising:
a semiconductor substrate;
a gate pad on the semiconductor substrate;
a gate bond pad on and electrically connected to the gate pad;
a first barrier layer between a bottom portion of gate bond pad and the gate pad in a first direction perpendicular to a top surface of the semiconductor substrate; and
a second barrier layer between the gate pad and the first barrier layer in the first direction.

11. The semiconductor device of claim 10, wherein the second barrier layer has a width in a second direction that is parallel to a top surface of the semiconductor substrate that exceeds that of a portion of the first barrier layer that is between the second barrier layer and a bottom portion of the gate bond pad.

12. The semiconductor device of claim 11, wherein a thickness of the second barrier layer is substantially uniform along the width of the second barrier layer in the second direction.

13. The semiconductor device of claim 10, wherein the gate bond pad is coupled to the gate pad via a contact hole having opposing sidewalls,
wherein a portion of the first barrier layer is on the opposing sidewalls of the contact hole, and
wherein a width of the second barrier layer in a second direction that is parallel to a top surface of the semiconductor substrate is greater than a width of the contact hole in the second direction.

14. The semiconductor device of claim 10, further comprising an isolation layer, wherein a portion of the isolation layer is between the second barrier layer and the gate bond pad.

15-16. (canceled)

17. The semiconductor device of claim 10, wherein the second barrier layer is on a top surface and a sidewall of the gate pad.

18. The semiconductor device of claim 10, wherein a material of the second barrier layer is different from a material of the first barrier layer.

19. The semiconductor device of claim 10, further comprising:
a semiconductor layer structure comprising an active region and an inactive region, wherein the gate pad is on the inactive region;
a gate finger on the active region and electrically connected to the gate pad; and
a third barrier layer on the gate finger.

20. The semiconductor device of claim 19, wherein the third barrier layer is on a top surface and a sidewall of the gate finger.

21-24. (canceled)

25. A semiconductor device, comprising:
a semiconductor layer structure;
a plurality of unit cell transistors that are electrically connected in parallel, each unit cell transistor including a gate finger that extends in a first direction on a top surface of the semiconductor layer structure, the gate fingers spaced apart from each other along a second direction; and
an auxiliary gate electrode barrier layer on an upper surface of each of the gate fingers.

26. The semiconductor device of claim 25, wherein the gate finger comprises polysilicon.

27. (canceled)

28. The semiconductor device of claim 25, wherein the auxiliary gate electrode barrier layer is also on opposing sidewalls of each of the gate fingers.

29. The semiconductor device of claim 25, wherein the semiconductor layer structure comprises an inactive region and an active region,
wherein the active region comprises the plurality of unit cell transistors, and
wherein the inactive region comprises:
a gate pad on the semiconductor layer structure;
a gate bond pad on and electrically connected to the gate pad;
an isolation layer between the gate pad and the gate bond pad; and
an auxiliary gate pad barrier layer between the gate pad and the isolation layer.

30. (canceled)

31. The semiconductor device of claim 29, further comprising a gate pad barrier layer between the auxiliary gate pad barrier layer and the gate bond pad.

32. (canceled)

33. The semiconductor device of claim 25, further comprising:
a source contact on the semiconductor layer structure;
a source barrier layer on sidewalls and a bottom surface of the source contact; and
an auxiliary source barrier layer between the semiconductor layer structure and the source barrier layer.

34. The semiconductor device of claim 25, further comprising an isolation layer on the gate finger,
wherein the auxiliary gate electrode barrier layer is between the isolation layer and the gate finger.
